(19) United States
(12) Patent Application Publication
(10) Pub. No.: US 2025/0318349 A1
(43) Pub. Date: Oct. 9, 2025

(54) LIGHT-EMITTING SUBSTRATE AND METHOD OF MANUFACTURING THE SAME

(71) Applicant: BOE TECHNOLOGY GROUP CO., LTD., Beijing (CN)

(72) Inventors: Tingting Zhou, Beijing (CN); Fangzhen Zhang, Beijing (CN); Jing Niu, Beijing (CN); Wei Wang, Beijing (CN); Yanan Niu, Beijing (CN); Shuang Sun, Beijing (CN)

(73) Assignee: BOE TECHNOLOGY GROUP CO., LTD., Beijing (CN)

(21) Appl. No.: 18/864,700

(22) PCT Filed: May 11, 2023
(86) PCT No.: PCT/CN2023/093522

§ 371 Date: Nov. 11, 2024

(30) Foreign Application Priority Data
May 12, 2022 (CN) 202210519285.4

(51) Int. Cl. H10H 29/855; H01L 25/075; H10H 29/01; H10H 29/24; H10H 29/856

(52) U.S. Cl. CPC H10H 29/8552; H10H 29/0363; H10H 29/24; H10H 29/856; H01L 25/0753

(57) ABSTRACT

A light-emitting substrate and a manufacturing method are provided. The light-emitting substrate includes a substrate and light-emitting devices arranged at intervals thereon. Light-shielding structure is at a gap between the light-emitting devices and shields light emitted from the light-emitting devices laterally. The light-shielding structure and light-emitting devices do not overlap in a target light-emitting direction of the light-emitting devices, or overlap in a target light-emitting direction of the light-emitting devices by being less than a width. Since the light-shielding structure is at the gap between the light-emitting devices, light emitted by the light-emitting devices laterally is shielded, avoiding light from irradiating other devices and causing light crosstalk. Light from the light-emitting devices in the target light-emitting direction is not shielded or not completely shielded, eliminating an adverse effect on light efficiency of the light-emitting devices, improving the light-emitting effect of the light-emitting surface of the light-emitting substrate.

### CROSS-REFERENCE TO RELATED APPLICATION

This application claims priority to the Chinese patent application No. 202210519285.4 filed in China on May 12, 2022, a disclosure of which is incorporated herein by reference in its entirety.

### TECHNICAL FIELD

The present disclosure relates to the technical field of light-emitting devices, in particular to a light-emitting substrate and a method of manufacturing the light-emitting substrate.

### BACKGROUND

A light-emitting diode (LED) is a mainstream of light-emitting devices, and has a wide range of applications. For example, the LED may be used as a light-emitting device in a backlight source of a liquid crystal display device. An LED device with a smaller size, such as a Micro LED and a Mini LED, may also be directly used for display.

Currently, in a device using an LED as a light-emitting device, a plurality of LED arrays are generally arranged. In a case that a gap between a plurality of LEDs is relatively small, light emitted laterally by each LED may be mixed with light emitted by another LED, resulting in obvious crosstalk of light. In the prior art, in order to solve this problem, a layer of black glue is provided. The black glue fills the gap between the LEDs to block the transmission of the light emitted laterally by the LED, thereby avoiding optical crosstalk. However, the method also has other problems. When the black glue is formed, the black glue not only fills the gap between the LEDs, but also covers the LED. The black glue covering the LED reduces the light emitted from the LED to the target light-emitting direction, and affects the light efficiency of the LED as the light-emitting device.

### SUMMARY

The present disclosure provides a light-emitting substrate and a method of manufacturing the light-emitting substrate to solve the foregoing technical problem in the prior art that the light efficiency of a light-emitting device is affected.

The present disclosure provides a light-emitting substrate, where the light-emitting substrate includes a substrate, and a plurality of light-emitting devices are arranged on the substrate at intervals; a first light-shielding structure is arranged at a gap between the plurality of light-emitting devices, and the first light-shielding structure is configured to shield light emitted from the plurality of light-emitting devices laterally; the first light-shielding structure and the plurality of light-emitting devices do not overlap in a target light-emitting direction of the plurality of light-emitting devices, or an overlapping region between the first light-shielding structure and the plurality of light-emitting devices in a target light-emitting direction of the plurality of light-emitting devices is less than a set value.

Optionally, a material of the first light-shielding structure is a black matrix or a metal.

Optionally, a material of the first light-shielding structure is one of molybdenum, copper, or aluminum.

Optionally, the plurality of light-emitting devices are LEDs.

Optionally, the first light-shielding structure is a single-layer or multi-layer structure.

Optionally, the light-emitting substrate further includes a second light-shielding structure, and the second light-shielding structure is located at a top end side of the plurality of light-emitting devices and away from a top end of the plurality of light-emitting devices; a projection of the second light-shielding structure on a surface where the plurality of light-emitting devices are located is located at the gap between the plurality of light-emitting devices.

Optionally, the light-emitting substrate has a plurality of layers of the second light-shielding structure, and the plurality of layers of the second light-shielding structure are sequentially arranged at intervals in a target light-emitting direction of the plurality of light-emitting devices.

Optionally, a material of the second light-shielding structure is a black matrix or a metal.

Optionally, a material of the second light-shielding structure is one of molybdenum, copper, or aluminum.

Optionally, the light-emitting substrate includes a light guide pillar, and a refractive index of a material of the light guide pillar is greater than a first set value; the light guide pillar corresponds to the plurality of light-emitting devices in a target light-emitting direction of the plurality of light-emitting devices.

Optionally, an inter-pillar structure is arranged between adjacent light guide pillars, a refractive index of the inter-pillar structure is less than a second set value, and the second set value is less than a first set value.

Optionally, a refractive index of the light guide pillar is 1.8-2.5.

Optionally, the refractive index of the inter-pillar structure is 1-1.5.

Optionally, the light-emitting substrate includes one or more planarization layers covering the plurality of light-emitting devices, and a light transmittance of each of the planarization layers covering the plurality of light-emitting devices is greater than 90%.

The present disclosure provides a method of manufacturing a light-emitting substrate, including:
forming a first light-shielding material layer: forming, on a substrate having light-emitting devices, the first light-shielding material layer covering the light-emitting devices and a gap between the light-emitting devices;
forming a first light-shielding structure: removing a pattern of a first light-shielding material layer covering on the light-emitting devices in at least partial region corresponding to the light-emitting devices to expose the at least partial region of the light-emitting devices.

Optionally, the material of the first light-shielding material layer is a black matrix; when removing the pattern of the first light-shielding material layer covering the light-emitting devices, an entire layer of the first light-shielding material layer is etched to thin the first light-shielding material layer to a height corresponding to the top of the light-emitting devices.

Optionally, when removing the pattern of the first light-shielding material layer covering the light-emitting devices, the pattern of the first light-shielding material layer covering the light-emitting devices is etched and removed through a mask exposure etching process.

Optionally, the first light-shielding material layer is a metal layer; the step of forming the first light-shielding structure further includes:
before removing the pattern of the first light-shielding material layer covering the light-emitting devices through the mask exposure etching process, forming a planarization layer;
thinning the planarization layer to expose the pattern of the first light-shielding material layer covering the light-emitting devices.

Optionally, the method of manufacturing a light-emitting substrate further includes:
forming a second light-shielding structure: forming a planarization layer, and forming a layer of light-shielding pattern in a region corresponding to a gap between the planarization layer and the light-emitting devices, where the light-shielding pattern is the second light-shielding structure.

Optionally, the method of manufacturing a light-emitting substrate further includes:
repeating the step of forming the second light-shielding structure to form a plurality of layers of the second light-shielding structure on the light-emitting substrate.

Optionally, the method of manufacturing a light-emitting substrate further includes:
forming a light guide pillar in a target light-emitting direction of the light-emitting devices, where a refractive index of a material of the light guide pillar is greater than a first set value.

Optionally, the method of manufacturing a light-emitting substrate further includes:
after forming the light guide pillar, depositing a layer of filling material, where the deposited filling material fills a gap between adjacent light guide pillars, a refractive index of the filled material is less than a second set value, and the second set value is less than the first set value.

Optionally, the method of manufacturing a light-emitting substrate further includes:
removing the filling material covering the light guide pillar.

The present disclosure provides a light-using device, including the foregoing light-emitting substrate.

Optionally, the light-using device is a backlight source, display device, or 3D printing device.

Compared with the prior art, the light-emitting substrate and the method of manufacturing the light-emitting substrate provided by the embodiments of the present disclosure have the following advantages:
for the light-emitting substrate provided by the embodiments of the present disclosure, the first light-shielding structure is arranged at the gap between the light-emitting devices, that is, the lateral position of the light-emitting devices. Thus, the first light-shielding structure can shield the light emitted by the light-emitting devices laterally, avoiding this part of the light from irradiating other light-emitting devices and causing light crosstalk. Moreover, in the target light-emitting direction of the light-emitting devices, the first light-shielding structure does not overlap with the light-emitting devices. Thus, the first light-shielding structure does not shield the light emitted by the light-emitting devices in the target light-emitting direction, which does not affect the light efficiency of the light-emitting devices and ensures that the light-emitting devices can emit enough light in the target light-emitting direction, and have enough brightness, thereby improving the light-emitting effect of the light-emitting surface of the light-emitting substrate.

The light-emitting substrate manufactured by the method of manufacturing the light-emitting substrate provided by the present disclosure is the same as the foregoing light-emitting substrate, has the same beneficial effects as the foregoing light-emitting substrate, and details are not described herein again.

### BRIEF DESCRIPTION OF THE DRAWINGS

The drawings herein are incorporated into the specification and constitute a part of the specification, show embodiments conforming to the present disclosure, and serve to, together with the specification, explain the principle of the present disclosure. In order to explain the technical solutions in embodiments of the present disclosure or the prior art more clearly, accompanying drawings of the embodiments or the prior art are briefly illustrated hereinafter. Apparently, the accompanying drawings described hereinafter are only some embodiments of the present disclosure, and those skilled in the art can further obtain other drawings according to the drawings without creative work.

FIG. 1 is a schematic structural diagram of a light-emitting substrate according to an embodiment of the present disclosure;

FIG. 2 is a schematic structural diagram of a top view direction of the light-emitting substrate shown in FIG. 1;

FIG. 3 is a schematic diagram of a light-emitting device of a light-emitting substrate emitting light laterally;

FIG. 4 is a schematic structural diagram of a light-emitting substrate according to another embodiment of the present disclosure;

FIG. 5 is a schematic structural diagram of a light-emitting substrate according to another embodiment of the present disclosure;

FIG. 6 is a schematic structural diagram of a light-emitting substrate according to another embodiment of the present disclosure;

FIG. 7 is a schematic structural diagram of a light-emitting substrate according to another embodiment of the present disclosure;

FIG. 8 is a schematic structural diagram of a light-emitting substrate according to another embodiment of the present disclosure;

FIG. 9 is a schematic structural diagram of a light-emitting substrate according to another embodiment of the present disclosure;

FIG. 10 is a schematic structural diagram of a light-emitting substrate according to another embodiment of the present disclosure;

FIG. 11 is a process flow diagram of a method of manufacturing a light-emitting substrate according to the present disclosure;

FIG. 12 is a schematic structural diagram of a substrate with light-emitting devices;

FIG. 13 is a schematic diagram of forming a first light-shielding material layer according to an embodiment;

FIG. 14 is a schematic diagram of forming a first light-shielding material layer according to another embodiment;

FIG. 15 is a schematic diagram of removing a first light-shielding material layer shielding light-emitting devices according to an embodiment;

FIG. 16 is a schematic diagram of removing a first light-shielding material layer shielding light-emitting devices according to another embodiment;

FIG. 17 is a process flow diagram of removing a first light-shielding material layer shielding light-emitting devices according to another embodiment;

FIG. 18 a schematic diagram of forming a planarization layer;

FIG. 19 is a schematic diagram of thinning a planarization layer;

FIG. 20 is a schematic diagram of removing a first light-shielding material layer shielding light-emitting devices;

FIG. 21 is a schematic diagram of forming a second light-shielding material layer according to an embodiment;

FIG. 22 is a schematic diagram of forming a second light-shielding structure according to an embodiment:

FIG. 23 is a schematic diagram of forming a planarization layer on a second light-shielding structure;

FIG. 24 is a schematic structural diagram of forming a light guide pillar according to an embodiment;

FIG. 25 is a schematic diagram of forming an inter-pillar structure according to an embodiment;

FIG. 26 is a schematic diagram of removing a portion of an inter-pillar structure above a light guide pillar according to an embodiment.

In the drawings:
10—substrate;
20—light-emitting device
30—first light-shielding structure; 301—first light-shielding material layer; 302—second light-shielding material layer;
40—second light-shielding structure;
50—light guide pillar; 51—inter-pillar structure;
60—planarization layer; 60a—first planarization layer; 60b—second planarization layer; 60c—third planarization layer.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a portion but not all of the embodiments of the disclosure. All other embodiments made on the basis of the embodiments of the present disclosure by a person of ordinary skill in the art without paying any creative effort shall be included in the protection scope of the present disclosure.

The embodiments of a light-emitting substrate and a method of manufacturing the light-emitting substrate provided by the present disclosure will be described below with reference to the accompanying drawings.

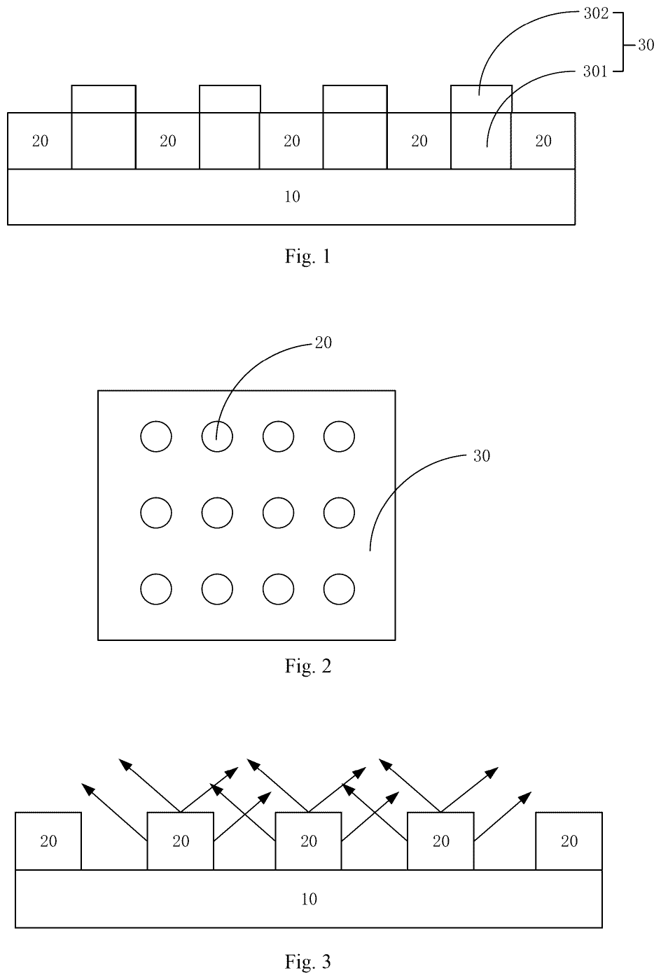

In an embodiment of a light-emitting substrate of the present disclosure, referring to FIG. 1 and FIG. 2, the light-emitting substrate includes a substrate 10, and a plurality of light-emitting devices 20 are arranged on the substrate 10 at intervals. The light-emitting device 20 may be specifically an LED. Furthermore, when an LED is used as the light-emitting device 20, a miniaturized LED device may be selected. For example, a Mini LED (the size of the LED chip is 100-300 μm) or a Micro LED (the size of the LED chip is less than 100 μm). Certainly, an LED with a common size (the size of the LED chip is greater than 300 μm) may also be used as the light-emitting device 20 and other types of light-emitting devices other than the LED may also be selected as the light-emitting device 20.

In terms of the light-emitting device 20 arranged on the substrate 10, fundamentally, the light-emitting device 20 can emit light in a target light-emitting direction. The target light-emitting direction is the direction in which the light-emitting substrate needs the light-emitting devices 20 to emit light, generally being the light-emitting surface of the light-emitting substrate. Taking FIG. 1 as an example, the light-emitting surface of the light-emitting substrate is the upper side direction in FIG. 1. The light-emitting substrate needs the light-emitting device 20 to emit light upwards to form light emitted from the light-emitting surface. Therefore, the upper side direction in FIG. 1 is the target light-emitting direction of the light-emitting device 20. In practice, in many cases, a light-emitting device 20, in addition to being able to emit light in the target light-emitting direction, may also emit light laterally, as shown in FIG. 3, irradiating other light-emitting devices 20 or irradiating the target light-emitting region of other light-emitting devices 20 (the region corresponding to the light-emitting device 20 in the target light-emitting direction), thereby causing light crosstalk.

Referring to FIG. 1 and FIG. 2, a first light-shielding structure 30 is arranged in a gap between the light-emitting devices 20. The first light-shielding structure 30 is configured to shield light emitted from the light-emitting devices 20 laterally. And the first light-shielding structure and the light-emitting devices do not overlap in a target light-emitting direction of the light-emitting devices. Specifically, the first light-shielding structure 30 includes a bottom portion, a side portion, and a top portion. As shown in FIG. 1, the bottom portion of the first light-shielding structure 30 faces the substrate 10. The side portion of the first light-shielding structure 30 faces the light-emitting devices 20 and surrounds the light-emitting devices 20. As shown in the example in FIG. 2, the first light-shielding structure 30 has a corresponding opening at each light-emitting device 20 position. The light-emitting device 20 is located within this opening, and the side portion of the first light-shielding structure 30 at this opening surrounds the light-emitting device 20. The top portion of the first light-shielding structure 30 is flush with or higher than a top end of the light-emitting devices 20, as shown in the examples in FIGS. 1, 4, and 5.

Specifically, the material of the first light-shielding structure 30 may be a black matrix or metal, both of which can effectively block the transmission of light. When forming the first light-shielding structure 30 with a black matrix or metal material, a material layer of black matrix or metal is commonly formed by deposition or sputtering, etc. The black matrix or metal material formed in this way may also cover the light-emitting device 20 at the same time. When manufacturing the light-emitting substrate of this embodiment, after completing the above process steps, the black matrix or metal material covering the light-emitting devices 20 can be removed by thinning or etching, etc. So that the formed first light-shielding structure 30 does not overlap with the light-emitting devices 20 in the target light-emitting direction of the light-emitting devices 20 and does not shield the light-emitting devices 20.

Specifically, when choosing to use metal to manufacture and form the first light-shielding structure 30, molybdenum, copper, aluminum, and other metal materials, etc. may be chosen. Moreover, metals with a high reflectivity may be preferably chosen. The first light-shielding structure 30 formed by a material with high reflectivity can not only block the light emitted by the light-emitting devices 20 laterally but also reflect this light as much as possible towards the light-emitting devices 20, allowing at least a part of the light to be emitted from the target light-emitting direction of the light-emitting devices 20. This increases the amount of light emitted from the target light-emitting direction of the light-emitting devices 20, thereby further improving the light-emitting effect.

The first light-shielding structure 30 is arranged at the gap between the light-emitting devices 20, that is, the lateral position of the light-emitting devices 20. Thus, the first light-shielding structure 30 can shield the light emitted by the light-emitting devices 20 laterally, avoiding this part of the light from irradiating other light-emitting devices 20 and causing light crosstalk. Moreover, in the target light-emitting direction of the light-emitting devices 20, the first light-shielding structure 30 does not overlap with the light-emitting devices 20. Thus, the first light-shielding structure 30 does not shield the light emitted by the light-emitting devices 20 in the target light-emitting direction, which does not affect the light efficiency of the light-emitting devices 20 and ensures that the light-emitting devices 20 can emit enough light in the target light-emitting direction, and have enough brightness, thereby improving the light-emitting effect of the light-emitting surface of the light-emitting substrate.

In other embodiments of the light-emitting substrate, the first light-shielding structure 30 and the light-emitting devices 20 may also overlap in the target light-emitting direction of the light-emitting devices 20 based on possible process errors or intentional settings, etc. It is only necessary for the overlapping region of the first light-shielding structure 30 and the light-emitting devices 20 in the target light-emitting direction of the light-emitting devices 20 to be less than a set value. By setting this set value to an appropriate size, the overlap of the first light-shielding structure 30 with the light-emitting devices 20 can be controlled so that the shielding of the light-emitting devices 20 by the overlapping region does not significantly affect the light emitted by the light-emitting devices 20 in the target light-emitting direction, keeping the affecting within an acceptable range, achieving and meeting the requirements of all performance parameters of the light-emitting substrate. Specifically, the specific type of this set value may be the absolute value of the area of the overlapping region of the first light-shielding structure 30 and the light-emitting devices 20 (for example, the area of the overlapping region of the first light-shielding structure 30 and the light-emitting devices 20 does not exceed a set value of 100 square micrometers), or may be the size of the overlapping region of the first light-shielding structure 30 and the light-emitting devices 20 relative to the light-emitting devices 20 (for example, the proportion of the overlapping region of the first light-shielding structure 30 and the light-emitting devices 20 in the light-emitting devices 20 does not exceed a set value of 10%).

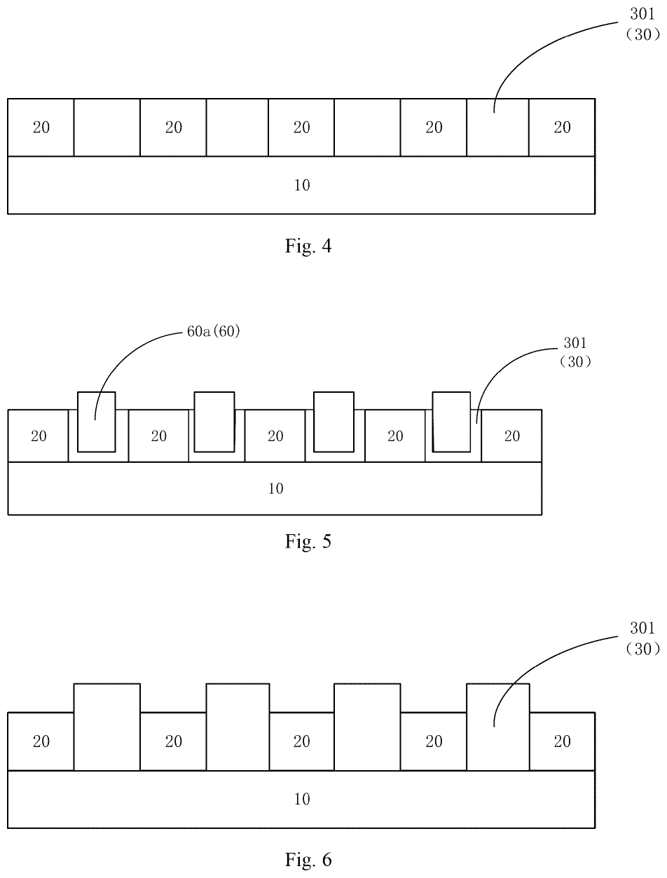

In an embodiment of the light-emitting substrate, as shown in FIG. 4 or 5, the first light-shielding structure 30 is flush with a top end of the light-emitting devices 20. In the structure shown in FIG. 4, the material of the first light-shielding structure 30 may be a black matrix. In the structure shown in FIG. 5, the material of the first light-shielding structure 30 may be metal. When the first light-shielding structure 30 is flush with the top end of the light-emitting devices 20, the light emitted from the side of the light-emitting devices 20 laterally can be effectively shield, effectively improving light crosstalk.

In another embodiment of the light-emitting substrate, as shown in FIGS. 1 and 6, the first light-shielding structure 30 may also be higher than the top end of the light-emitting devices 20. When the first light-shielding structure 30 is higher than the top end of the light-emitting devices 20, not only the light emitted from the side of the light-emitting devices 20 laterally can be effectively shielded by the first light-shielding structure 30. But also, for the light emitted by the light-emitting devices 20 towards the side of the target light-emitting direction and inclined laterally, when part of the light is irradiated on the first light-shielding structure 30, the first light-shielding structure 30 can naturally shield the continued sideways emission of this part of the light, achieving shielding this part of the light. Essentially, in this case, a part of the top end of the first light-shielding structure 30 that is higher than the top end of the light-emitting device 20 plays a role and effect of collimating the light emitted by the light-emitting device 20 towards the target light-emitting direction, so that crosstalk of light can be further improved.

In an embodiment of the light-emitting substrate, the first light-shielding structure 30 may be a single-layer structure, as shown in FIG. 4 or 6, or may be a multi-layer structure, as shown in FIG. 1. When the first light-shielding structure 30 is a single-layer structure, for example, when the material of the first light-shielding structure 30 is a black matrix, the black matrix may be coated and cured multiple times. The black matrix formed in this way is considered a single-layer structure. When the first light-shielding structure 30 is a multi-layer structure, for example, the first light-shielding structure 30 may include a first light-shielding material layer 301 and a second light-shielding material layer 302. The material of each layer may be different, or may be the same but formed in sequence by different process steps (with other process steps in between) and superimposed together.

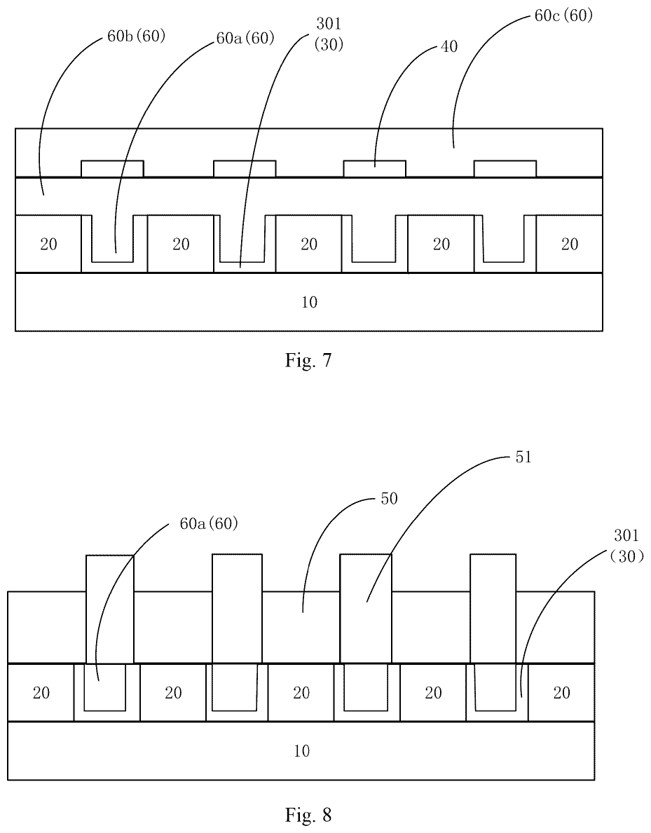

In an embodiment of the light-emitting substrate, as shown in FIG. 7, the light-emitting substrate also includes a second light-shielding structure 40. The second light-shielding structure 40 is located at a top end side of the light-emitting devices 20 (in the figure, being located at the upper side of the light-emitting devices 20), and is away from the top end of the light-emitting devices 20. A projection of the second light-shielding structure 40 on a surface where the light-emitting devices 20 are located is located at the gap between the light-emitting devices 20 (not limited to the case where the projection of the second light-shielding structure 40 is located within the gap between the light-emitting devices 20, the projection of the second light-shielding structure 40 may also partially exceed the gap between the light-emitting devices 20 and overlap with the light-emitting devices 20). As can be seen from FIG. 7, the second light-shielding structure 40 is not in the target light-emitting direction of the light-emitting devices 20, if the target light-emitting direction of the light-emitting devices 20 is up, then the second light-shielding structure 40 is located on the oblique upper side of the light-emitting devices 20. When the light-emitting devices 20 emit light, for the light emitted upwards according to the target light-emitting direction, the second light-shielding structure 40 is not in its light path and does not produce shielding. But for the light emitted towards the oblique upper side, part of the light is irradiated on the second light-shielding structure 40, for this part of the light, the second light-shielding structure 40 can block the propagation of this part of the light. The blocking of this part of the light that is emitted inclined relative to the target light-emitting direction plays a collimating role and effect, which can improve the light crosstalk.

In the structure shown in FIG. 7, the first light-shielding structure 30 is flush with the top end of the light-emitting devices 20. But it should be noted that, in this embodiment, the first light-shielding structure 30 may also be higher than the top of the light-emitting devices 20, as shown in FIGS. 1 and 6. When the first light-shielding structure 30 is higher than the top of the light-emitting devices 20, the part of the first light-shielding structure 30 that is higher than the top of the light-emitting devices 20, and the second light-shielding structure 40 can both collimate the light emitted by the light-emitting devices 20 towards the target light-emitting direction, the combined action can achieve a better collimating effect, and thus better improve the light crosstalk.

In a further embodiment of the light-emitting substrate, the light-emitting substrate has a plurality of layers of the second light-shielding structure 40, and the plurality of layers of the second light-shielding structure 40 are sequentially arranged at intervals in a target light-emitting direction of the light-emitting devices 20 (not shown in the figure). When the second light-shielding structure 40 is multi-layered, in the light emitted by the light-emitting devices 20 inclined relative to the target light-emitting direction, the light irradiated on the second light-shielding structure 40 and shielded by the second light-shielding structure 40 is more, so multiple second light-shielding structures 40 can achieve a better collimating effect, and thus better improve the light crosstalk.

Specifically, similar to the first light-shielding structure 30, the material of the second light-shielding structure 40 may also be a black matrix or metal. When the material of the second light-shielding structure 40 is metal, molybdenum, copper, aluminum, or other metal materials, etc. may be chosen. But different from the first light-shielding structure 30, for the second light-shielding structure 40, the second light-shielding structure 40 preferably chooses metal or other materials with a lower reflectivity, or materials with a good light absorption effect. The second light-shielding structure 40 made of these preferred materials can better reflect the light irradiated on it, avoiding the reflected light from entering the region corresponding to other light-emitting devices 20 and causing light crosstalk.

In an embodiment of the light-emitting substrate, as shown in FIG. 8, the light-emitting substrate includes a light guide pillar 50. The refractive index of the material of the light guide pillar 50 is greater than a first set value. The light guide pillar 50 corresponds to the light-emitting devices 20 in the target light-emitting direction of the light-emitting devices 20.

In the target light-emitting direction of the light-emitting devices 20, the light guide pillar 50 corresponds to the light-emitting devices 20, which means that the light guide pillar 50 is located on the propagation path of the light emitted by the light-emitting devices 20 towards the target light-emitting direction. The light emitted from the side of the light-emitting devices 20 towards the target light-emitting direction includes light with an emission direction strictly consistent with the target light-emitting direction, and light with an emission direction inclined relative to the target light-emitting direction, and enters the light guide pillar 50 from the end of the light guide pillar 50 facing the light-emitting device 20.

For the light with an emission direction strictly consistent with the target light-emitting direction, the light may emit from one end of the light guide pillar 50 towards the light-emitting surface of the light-emitting substrate in the light guide pillar 50 according to the emission direction strictly consistent with the target light-emitting direction, and finally emit to the outside from the light-emitting surface of the light-emitting substrate. In this process, this part of the light does not contact the side wall of the light guide pillar 50.

For the light with an emission direction inclined relative to the target light-emitting direction, the part with a smaller inclination angle, when propagating in the light guide pillar 50, may also irradiate the end of the light guide pillar 50 facing the light-emitting surface of the light-emitting substrate and emit, without irradiating the side wall of the light guide pillar 50. This part of the light can be considered equivalent to the foregoing light with an emission direction strictly consistent with the target light-emitting direction and may also directly reach the end of the light guide pillar 50 facing the light-emitting surface of the light-emitting substrate from the end of the light guide pillar 50 facing the light-emitting devices 20 to, and emit to the outside from the light-emitting surface of the light-emitting substrate.

And for light that is emitted inclined relative to the target light-emitting direction with a larger inclination angle, the light irradiates the side wall of the light guide pillar 50 when propagating in the light guide pillar 50. For this part of the light, by choosing to set a suitable first set value, the refractive index of the light guide pillar 50 may be made higher, and higher than the refractive index of the region between the light guide pillars 50. In this case, the part of the light irradiating the side wall of the light guide pillar 50 at an angle that meets the requirements may undergo total reflection, and may not undergo refraction and emit from the side wall direction of the light guide pillar 50, thus reducing the light that emit laterally and irradiate the region of other light-emitting devices 20, thereby improving light crosstalk. At the same time, this part of the light undergoes total reflection, is constrained within the light guide pillar 50 and propagates towards the end of the light guide pillar 50 facing the light-emitting surface of the light-emitting substrate, which can also increase the amount of the light emitted from the target light-emitting direction, improve the brightness of the light, and provide a better light-emitting effect. Specifically, the refractive index of the light guide pillar 50 may be set between 1.8 and 2.5.

In an embodiment of the light-emitting substrate, as shown in FIG. 8, there is an inter-pillar structure 51 between adjacent light guide pillars 50, the refractive index of the inter-pillar structure 51 is less than a second set value, the second set value is less than the first set value. By choosing to set a suitable second set value, the condition for the light in the light guide pillar 50 to undergo total reflection at the side wall of the light guide pillar 50 can be made lower, so that more light can more easily undergo total reflection, achieving a better improvement in light crosstalk and collimation effect. Specifically, the refractive index of the inter-pillar structure 51 may be set between 1 and 1.5.

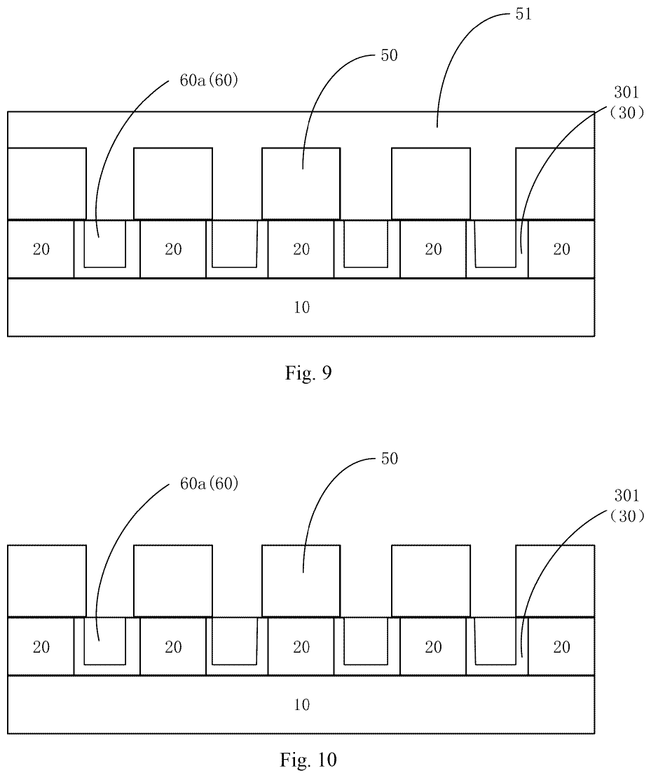

In this embodiment, as shown in FIG. 8, the inter-pillar structure 51 may only be located at the positions corresponding to the gap between the light-emitting devices 20 and the gap between the light guide pillars 50, without covering the light guide pillars 50, affecting the transmittance in the target light-emitting direction. In addition, if in the manufacturing process of the inter-pillar structure 51, partial region of the formed inter-pillar structure 51 may cover the light guide pillar 50, when the material of the inter-pillar structure 51 does not significantly affect the transmittance, this part of the inter-pillar structure 51 may be retained, as shown in FIG. 9, to reduce the process and time to remove this part.

In other embodiments of the light-emitting substrate, between adjacent light guide pillars 50, a special inter-pillar structure 51 may also not be formed, the region between adjacent light guide pillars 50 may be left empty, as shown in FIG. 10. The refractive index of air is slightly greater than 1. In this case, a suitable first set value may be set, such as the foregoing refractive index range of 1.8 to 2.5, so that the refractive index of the light guide pillar 50 can meet the requirement for the light in the light guide pillar 50 to undergo total reflection at the side wall of the light guide pillar 50.

In an embodiment of the present disclosure, the light-emitting substrate may include one or more planarization layers 60 covering the light-emitting devices 20. For example, in the embodiment shown in FIG. 7, the light-emitting substrate has three planarization layers 60. The three planarization layers 60 are all located above the light-emitting devices 20. The first planarization layer 60a is formed above the first light-shielding structure 30 (after formation, part of the first planarization layer 60a is thinned and removed in subsequent processes, the reserved part is connected to the second planarization layer 60b). The second planarization layer 60b is below the second light-shielding structure 40. The third planarization layer 60c is above the second light-shielding structure. In this embodiment, for each planarization layer 60, the transmittance of each planarization layer 60 covering the light-emitting devices 20 is greater than 90%. The greater the transmittance of the planarization layer 60, the more light can be emitted from the light-emitting surface of the light-emitting substrate, and the higher the brightness limit of the light-emitting surface of the light-emitting substrate.

According to the method of manufacturing the light-emitting substrate provided by the present disclosure, the light-emitting substrate described in the foregoing embodiments of the light-emitting substrate can be manufactured.

In an embodiment of the present disclosure, the method of manufacturing the light-emitting substrate includes the following steps S1-S3, as shown in FIG. 11.

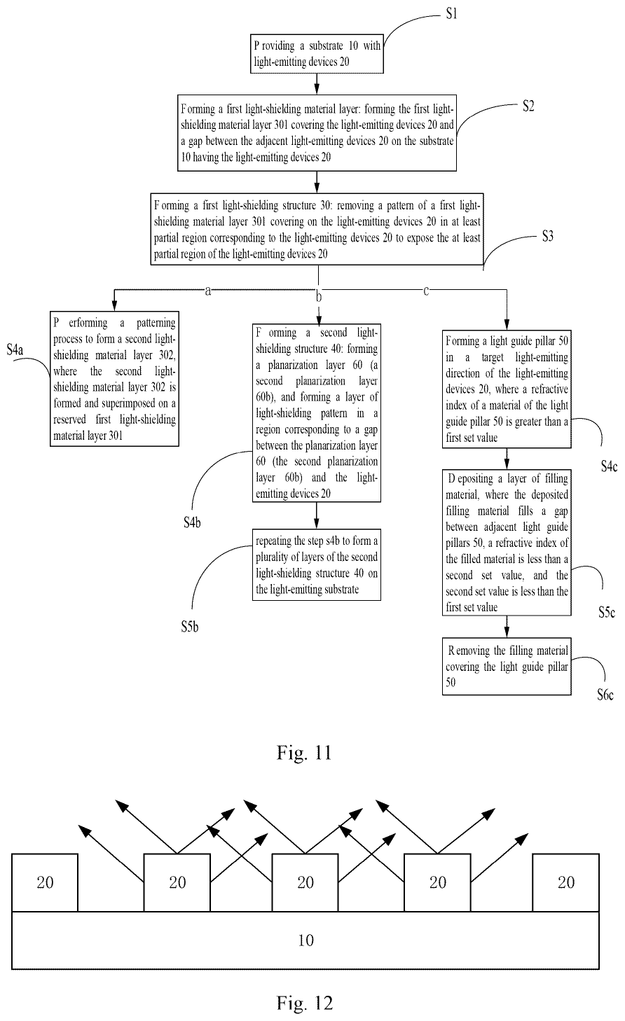

Step S1: providing a substrate 10 with light-emitting devices 20, as shown in FIG. 12.

In step S1, the substrate 10 may be a rigid substrate such as a conventional glass substrate, or may be a flexible substrate such as ultra-thin glass or polyimide.

There are commonly a plurality of light-emitting devices 20 on the substrate 10. Each light-emitting device 20 may be an LED, or may be other types of light-emitting device other than an LED. When an LED is selected as the light-emitting device 20, a miniaturized LED device may be selected. For example, a Mini LED (the size of the LED chip is 100-300 μm) or a Micro LED (the size of the LED chip is less than 100 μm). Certainly, an LED with a common size (the size of the LED chip is greater than 300 μm) may also be used as the light-emitting device 20.

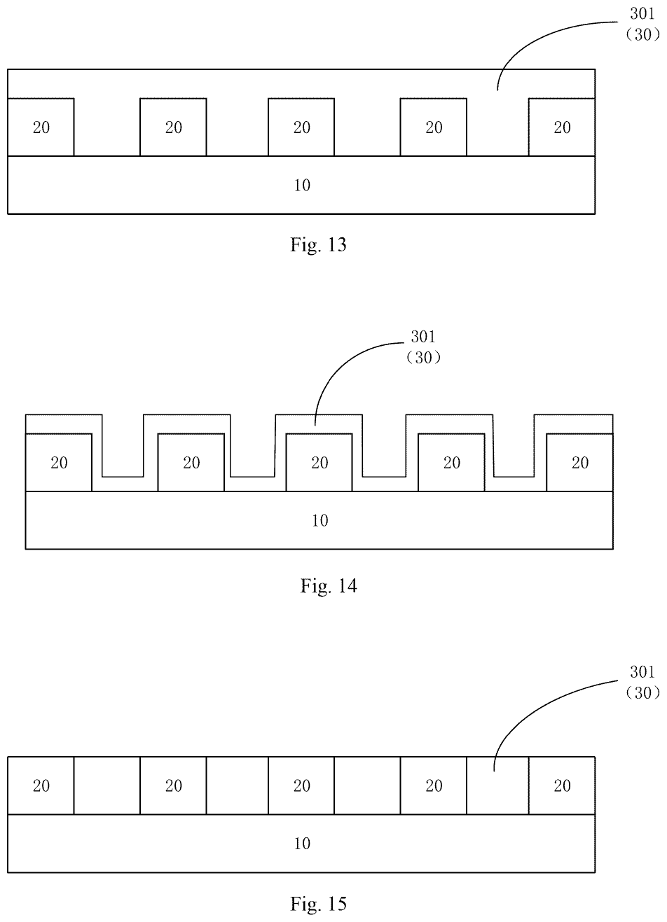

Step S2: forming a first light-shielding material layer: forming the first light-shielding material layer 301 covering the light-emitting devices 20 and a gap between the adjacent light-emitting devices 20 on the substrate 10 having the light-emitting devices 20, as shown in FIG. 13 and FIG. 14.

In step S2, the material of the first light-shielding material layer 301 may be a black matrix or metal, and a metal such as molybdenum, copper, aluminum, or another metal may be selected.

As shown in FIG. 13 and FIG. 14, when the first light-shielding material layer 301 is formed on the substrate 10, the first light-shielding material layer 301 not only covers the gap between the adjacent light-emitting devices 20, but also covers the light-emitting devices 20.

Step S3: forming a first light-shielding structure 30: removing a pattern of a first light-shielding material layer 301 covering on the light-emitting devices 20 in at least partial region corresponding to the light-emitting devices 20 to expose the at least partial region of the light-emitting devices 20.

In the structure after the step S3 is completed, the exposed region of the light-emitting device 20 should be above a set lower limit value, that is, the light-emitting device 20 is covered by the reserved first light-shielding material layer 301, and the region where the light-emitting device 20 and the light-emitting device 20 overlap should be smaller than a set value. The type of this set value may be the absolute value of the area of the overlapping region of the first light-shielding structure 30 and the light-emitting devices 20, or may be the proportion of the overlapping region of the first light-shielding structure 30 and the light-emitting devices 20 relative to the light-emitting devices 20.

In an embodiment of the present disclosure, the material of the first light-shielding material layer 301 is a black matrix. In step S3, when the pattern of the first light-shielding material layer 301 covering the light-emitting devices 20 is removed based on, for example, the pattern of the first light-shielding material layer 301 shown in FIG. 13, an entire layer of the first light-shielding material layer 301 is etched, to thin the first light-shielding material layer 301 to a height corresponding to the top of the light-emitting devices 20, so that at least a part of the region of the light-emitting device 20 is exposed. In the above process, selective etching does not need to be performed by using a mask. As shown in FIG. 15, the structure shown in FIG. 15 is a case where the reserved first light-shielding material layer 301 does not overlap with the light-emitting devices 20, and all the light-emitting devices 20 are exposed.

The light-emitting substrate having the structure shown in FIG. 15, a part of the first light-shielding material layer 301 reserved between the adjacent light-emitting devices 20 can shield light emitted from the side of the light-emitting device 20 laterally. The part of the light does not enter the regions of the other light-emitting devices 20, so that for the light-emitting substrate, the light crosstalk and the light-emitting effect of the light-emitting substrate can be improved.

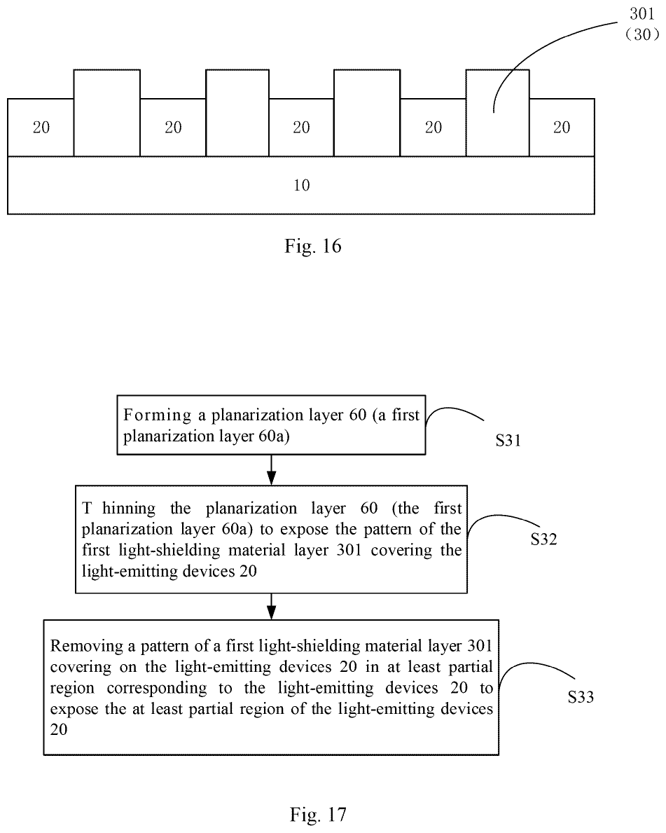

In another embodiment of the present disclosure, the material of the first light-shielding material layer 301 is also a black matrix. In step S3, when the pattern of the first light-shielding material layer 301 covering the light-emitting devices 20 is removed based on, for example, the pattern of the first light-shielding material layer 301 shown in FIG. 13, the pattern of the first light-shielding material layer 301 covering the light-emitting device 20 is removed through a mask exposure etching process, as shown in FIG. 16. Compared with the embodiment of FIG. 15, in this embodiment, the pattern of the first light-shielding material layer 301 is selectively etched by using the mask, so that at least a part of the region of the light-emitting devices 20 is exposed. After etching, the reserved first light-shielding material layer 301 is higher than the top end of the light-emitting devices 20. FIG. 16 shows a situation where the reserved first light-shielding material layer 301 does not overlap with the light-emitting devices 20, and all the light-emitting devices 20 are exposed.

The light-emitting substrate having the structure shown in FIG. 16, where a reserved portion of the first light-shielding material layer 301 is between the adjacent light-emitting devices 20 and has a height higher than the height of the light-emitting devices 20. Compared with the light-emitting substrate having the structure shown in FIG. 15, the light emitted by the light-emitting devices 20 laterally can be shield. Compared to the light emitted from the side of the light-emitting devices 20, this specific portion of light is more substantial. So that for this light-emitting substrate, the light crosstalk and the light-emitting effect of the light-emitting substrate can be better improved. In essence, a portion of the first light-shielding material layer 301 that is higher than the light-emitting devices 20 also plays a role in collimating light emitted from the light-emitting devices 20 to the target light-emitting direction.

In another embodiment of the present disclosure, the first light-shielding material layer 301 may be a metal layer, and may specifically be molybdenum, copper, aluminum, or other metal materials, and is preferably made of a material with a high reflectivity during implementation. In this embodiment, the step of forming the first light-shielding structure 30 in step S3 includes the following steps S31 to S33, as shown in FIG. 17.

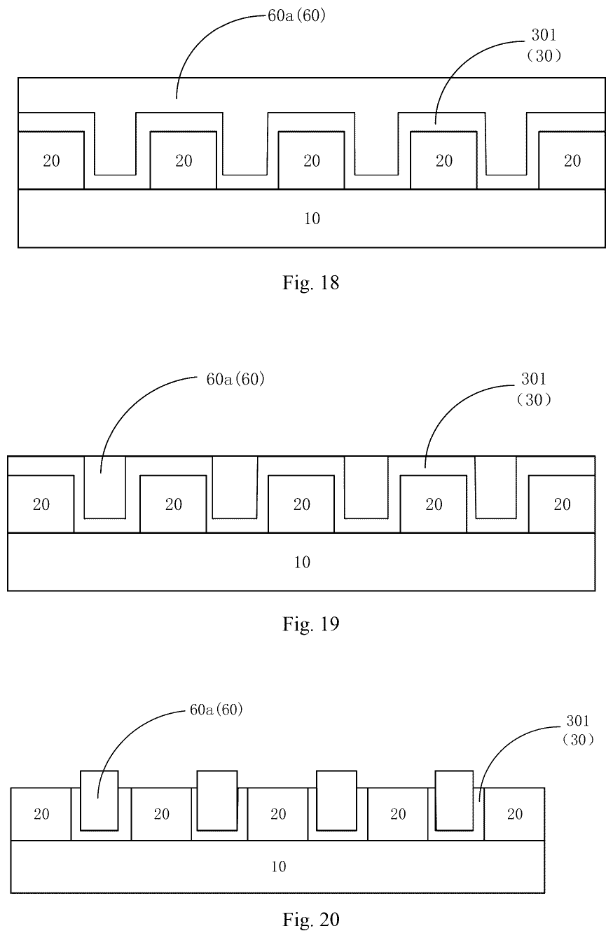

Step S31: a planarization layer 60 (a first planarization layer 60a) is formed, as shown in FIG. 18.

Before step S31, since the light-emitting device 20 protrudes relative to the substrate 10, the surface of the substrate 10 is not flat. The surface of the first light-shielding material layer 301 formed in step S2 is not flat. By step S31, a flat surface can be formed, which facilitates subsequent processing.

Step S32: thinning the planarization layer 60 (the first planarization layer 60a) to expose the pattern of the first light-shielding material layer 301 covering the light-emitting devices 20, as shown in FIG. 19.

In step S32, a maskless process is used to non-selectively etch the entire planarization layer 60 (the first planarization layer 60a), thinning the planarization layer 60 (the first planarization layer 60a) until the pattern of the first light-shielding material layer 301 that corresponds to the region of the light-emitting devices 20 is exposed. This facilitates subsequent etching of the pattern in the first light-shielding material layer 301 of the exposed region.

Step S33: removing a pattern of a first light-shielding material layer 301 covering on the light-emitting devices 20 in at least partial region corresponding to the light-emitting devices 20 to expose the at least partial region of the light-emitting devices 20, as shown in FIG. 20.

In step S33, through the mask exposure etching patterning process, the exposed pattern of the first light-shielding material layer 301 is removed, that is, the region of the first light-shielding material layer 301 corresponding to the light-emitting devices 20. The first light-shielding material layer 301 and the planarization layer 60 (the first planarization layer 60a) in other regions are reserved, and finally at least partial region of the light-emitting devices 20 is exposed. FIG. 20 shows the situation where the reserved first light-shielding material layer 301 does not overlap with the light-emitting devices 20, and all the light-emitting devices 20 are exposed.

In an embodiment of the present disclosure, on the basis of the structures shown in FIG. 15, FIG. 16 and FIG. 20, the process steps of sequence a are continue to be performed, and the process steps of the sequence a include step S4a.

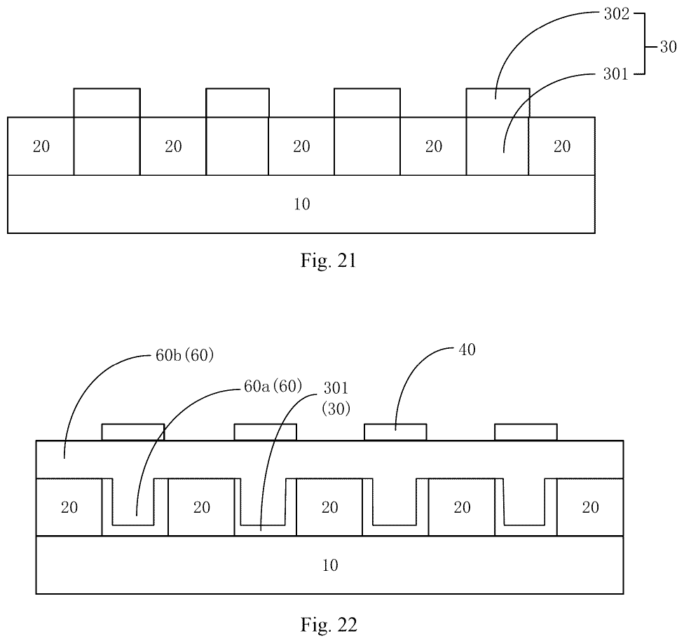

Step S4a: performing a patterning process to form a second light-shielding material layer 302, where the second light-shielding material layer 302 is formed and superimposed on a reserved first light-shielding material layer 301. Based on the structure shown in FIG. 15, the structure shown in FIG. 21 is obtained in step S4a.

In step S4a, the material of the second light-shielding material layer 302 may be the same as or different from the material of the first light-shielding material layer 301. For example, when the material of the first light-shielding material layer 301 is a black matrix, the material of the second light-shielding material layer 302 may be a black matrix or a metal. When the material of the first light-shielding material layer 301 is metal, the second light-shielding material layer 302 may be a black matrix, or may be a same metal material or a different metal material.

In the embodiment based on step S4a, the first light-shielding material layer 301 and the second light-shielding material layer 302 together constitute the first light-shielding structure 30. This is different from the embodiments based on step S3 (referring to FIGS. 15, 16, and 20), where in the foregoing embodiments, the first light-shielding structure 30 consists only of the first light-shielding material layer 301.

In the condition where the height of the first light-shielding material layer 301 reserved in step S3 is flush with the top end of the light-emitting devices 20, the second light-shielding material layer 302 formed and superimposed on top of the first light-shielding material layer 301 in step S4 can make the first light-shielding structure 30 rise above the top end of the light-emitting devices 20, thus producing a collimating effect. On the other hand, in the situation where the height of the first light-shielding material layer 301 reserved in step S3 is higher than the top end of the light-emitting devices 20, the second light-shielding material layer 302 formed and superimposed on top of the first light-shielding material layer 301 in step S4 can further increase the height of the first light-shielding structure 30, making the height of the first light-shielding structure 30 significantly higher than the top end of the light-emitting devices 20, thereby achieving even better collimation effects. In summary, the formation of the second light-shielding material layer 302 in step S4 can further improve the light crosstalk.

In another embodiment of the present disclosure, on the basis of the structures shown in FIG. 15, FIG. 16 and FIG. 20, the process steps of sequence b may be also continued to perform, and the process steps of the sequence b include the following step S4b.

Step S4b: forming a second light-shielding structure 40: forming a planarization layer 60 (a second planarization layer 60b), and forming a layer of light-shielding pattern in a region corresponding to a gap between the planarization layer 60 (the second planarization layer 60b) and the light-emitting devices 20, where the light-shielding pattern is the second light-shielding structure 40. Based on the structure shown in FIG. 20, the structure shown in FIG. 22 is obtained in step S4b.

In step S4b, the light-shielding pattern may be formed by a patterning process using mask exposure and selective etching. Specifically, when the light-shielding pattern is formed, opaque materials such as a black matrix and a metal material may be used. When the second light-shielding structure 40 is made of metal, molybdenum, copper, aluminum or other metal materials may be selected. However, it is different from the first light-shielding structure 30 that, for the second light-shielding structure 40, the second light-shielding structure 40 is preferably a metal or other material with a lower reflectivity, or a material with a good light absorption effect. The second light-shielding structure 40 made of these preferred materials can better reflect the light irradiated thereon, so as to prevent the reflected light from entering the regions corresponding to the other light-emitting devices 20 and generating the light crosstalk.

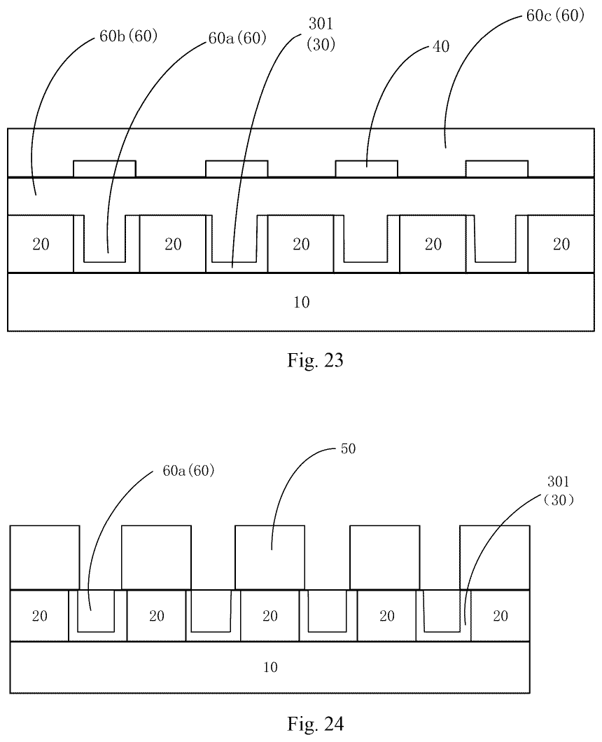

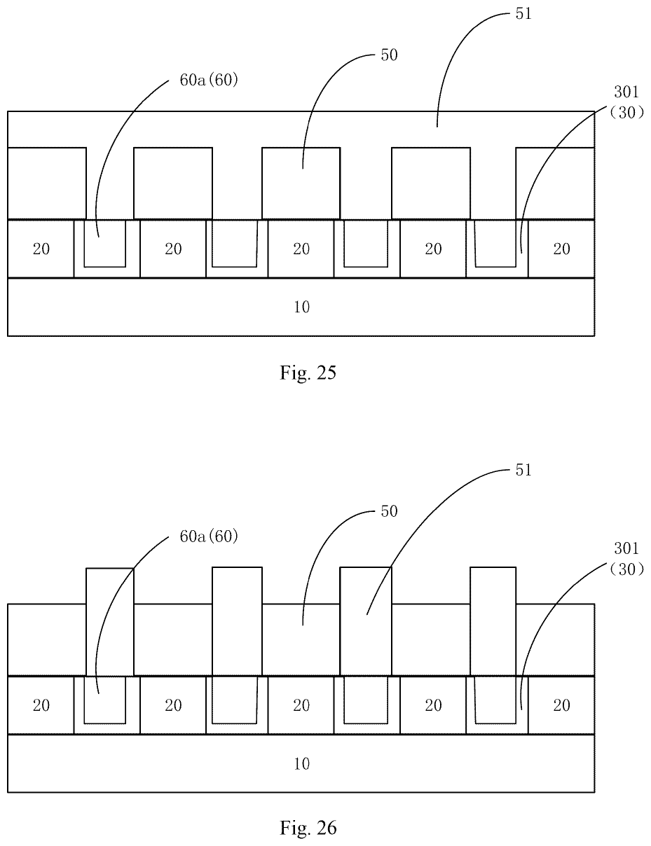

After step S4b, in order to make the surface flat and facilitate the subsequent processes, a planarization layer 60 (a third planarization layer 60c) may be further formed above the second light-shielding structure 40, as shown in FIG. 23.

In a further preferred embodiment of the present disclosure, the process steps of the sequence b may further include the following step S5b.

Step S5b: repeating the step of forming the second light-shielding structure 40 to form a plurality of layers of the second light-shielding structure 40 on the light-emitting substrate.

When the second light-shielding structure 40 is multi-layered, in the light emitted by the light-emitting devices 20 inclined relative to the target light-emitting direction, the light irradiated on the second light-shielding structure 40 and shielded by the second light-shielding structure 40 is more, so multiple second light-shielding structures 40 can achieve a better collimating effect, and thus better improve the light crosstalk.

In another embodiment of the present disclosure, on the basis of the structures shown in FIG. 15, FIG. 16 and FIG. 20, the process steps of sequence c may be also continued to perform, and the process steps of the sequence c include the following step S4c.

Step S4c: forming a light guide pillar 50 in a target light-emitting direction of the light-emitting devices 20, where a refractive index of a material of the light guide pillar 50 is greater than a first set value. Based on the structure shown in FIG. 20, the structure shown in FIG. 24 is obtained in step S4c.

In the target light-emitting direction of the light-emitting devices 20, the formed light guide pillar 50 corresponds to the light-emitting devices 20, which means that the light guide pillar 50 is located on the propagation path of the light emitted by the light-emitting devices 20 towards the target light-emitting direction. The light emitted from the side of the light-emitting devices 20 towards the target light-emitting direction includes light with an emission direction strictly consistent with the target light-emitting direction, and light with an emission direction inclined relative to the target light-emitting direction, and enters the light guide pillar 50 from the end of the light guide pillar 50 facing the light-emitting device 20.

For the light with an emission direction strictly consistent with the target light-emitting direction, the light may emit from one end of the light guide pillar 50 towards the light-emitting surface of the light-emitting substrate in the light guide pillar 50 according to the emission direction strictly consistent with the target light-emitting direction, and finally emit to the outside from the light-emitting surface of the light-emitting substrate. In this process, this part of the light does not contact the side wall of the light guide pillar 50.

For the light with an emission direction inclined relative to the target light-emitting direction, the part with a smaller inclination angle, when propagating in the light guide pillar 50, may also irradiate the end of the light guide pillar 50 facing the light-emitting surface of the light-emitting substrate and emit, without irradiating the side wall of the light guide pillar 50. This part of the light can be considered equivalent to the foregoing light with an emission direction strictly consistent with the target light-emitting direction and may also directly reach the end of the light guide pillar 50 facing the light-emitting surface of the light-emitting substrate from the end of the light guide pillar 50 facing the light-emitting devices 20 to, and emit to the outside from the light-emitting surface of the light-emitting substrate.

And for light that is emitted inclined relative to the target light-emitting direction with a larger inclination angle, the light irradiates the side wall of the light guide pillar 50 when propagating in the light guide pillar 50. For this part of the light, by choosing to set a suitable first set value, the refractive index of the light guide pillar 50 may be made higher, and higher than the refractive index of the region between the light guide pillars 50. In this case, the part of the light irradiating the side wall of the light guide pillar 50 at an angle that meets the requirements may undergo total reflection, and may not undergo refraction and emit from the side wall direction of the light guide pillar 50, thus reducing the light that emit laterally and irradiate the region of other light-emitting devices 20, thereby improving light crosstalk. At the same time, this part of the light undergoes total reflection, is constrained within the light guide pillar 50 and propagates towards the end of the light guide pillar 50 facing the light-emitting surface of the light-emitting substrate, which can also increase the amount of the light emitted from the target light-emitting direction, improve the brightness of the light, and provide a better light-emitting effect. Specifically, the refractive index of the light guide pillar 50 may be set between 1.8 and 2.5.

In step S4c, the formation of the light-guiding pillar 50 may be achieved through transfer printing, nanoimprinting, or by selective etching after exposure using a hard mask.

In a further preferred embodiment of the present disclosure, the process steps of the sequence e may further include the following step S5c.

Step S5c: after forming the light guide pillar 50, depositing a layer of filling material, where the deposited filling material fills a gap between adjacent light guide pillars 50, a refractive index of the filled material is less than a second set value, and the second set value is less than the first set value.

The material filled in step S5c is formed as an inter-pillar structure 51 between the light guide pillars 50.

In step 5c, by choosing to set a suitable second set value, the condition for the light in the light guide pillar 50 to undergo total reflection at the side wall of the light guide pillar 50 can be made lower, so that more light can more easily undergo total reflection, achieving a better improvement in light crosstalk and collimation effect. Specifically, the refractive index of the inter-pillar structure 51 may be set between 1 and 1.5.

In a further preferred embodiment of the present disclosure, the process steps of the sequence c may further include the following step S6c.

Step 6c: removing the filling material covering the light guide pillar 50, as shown in FIG. 26.

In the process of forming the inter-pillar structure 51 in step S5c, the inter-pillar structure 51 may only be located at the positions corresponding to the gap between the light-emitting devices 20 and the gap between the light guide pillars 50, and may also cover the light guide pillar 50. The part of the inter-pillar structure 51 covering the light guide pillar 50 may absorb light emitted from one side of the light guide pillar 50 facing the light-emitting surface of the light-emitting substrate, which affects the light efficiency of the light emitted by the light-emitting devices 20 to a certain extent, and affects the brightness upper limit of the light-emitting surface of the light-emitting substrate.

In step S6c, the part of the inter-pillar structure 51 covering the light guide pillar 50 is removed, so that the adverse effect of the inter-pillar structure 51 on the transmission of light emitted by the light-emitting devices 20 can be eliminated, the light transmittance of the light in the target light-emitting direction is improved, and the brightness upper limit of the light-emitting surface of the light-emitting substrate is increased.

The present disclosure further provides a light-using device, and in an embodiment of the present disclosure, the light-using device includes the light-emitting substrate described in the foregoing embodiments of the light-emitting substrate.

In an embodiment, the light-using device may be specifically a backlight source, which may be used in, for example, a liquid crystal display panel to provide backlight. When the light-using device is a backlight source, the backlight source of the light-emitting substrate can achieve more accurate local dimming due to the improvement of the light crosstalk.

In another embodiment, the light-using device may be a display device. For example, when the light-emitting device is a Mini LED or a Micro LED, each Mini LED or Micro LED can be used as a separate pixel or sub-pixel, and may be directly used for display.

In another embodiment, the light-using device may also be a 3D printing device. In the 3D printing device using the light-emitting substrate described above, due to the improvement of the light crosstalk, the pattern can be printed more accurately, and the printing precision is improved.

It should also be noted that, as used herein, relational terms such as first and second and the like are only used to distinguish one entity from another entity or one operation from another operation, but not necessarily require or imply that these entities or operations have any such actual relationship or order thereinbetween. In addition, the terms “comprise”, “include” and any other variations thereof intend to cover nonexclusive inclusion so that the procedure, the method, the product or the equipment including a series of elements include not only these elements, but also other elements which are not listed explicitly, or also include inherent elements of these procedure, method, product or equipment. In the case that there is no further limitation, elements defined by the expressions “comprise one . . . ” do not exclude there being additional identity elements in the procedure, method, product or equipment of the elements.

The above description is merely specific implementations of the present disclosure and allows one skilled in the art to understand or implement the present disclosure. Various modifications to these Examples would be apparent to one skilled in the art, and the general principles defined herein may be applied to other Examples without departing from the spirit or scope of the disclosure. Therefore, the present disclosure will not be limited to the Examples shown herein, but should conform to the widest scope consistent with the principles and novel features disclosed herein.

1. A light-emitting substrate, wherein the light-emitting substrate comprises a substrate, and a plurality of light-emitting devices is arranged on the substrate at intervals;
a first light-shielding structure is at a gap between the plurality of light-emitting devices, and the first light-shielding structure is configured to shield light emitted from the plurality of light-emitting devices laterally;
the first light-shielding structure and the plurality of light-emitting devices do not overlap in a target light-emitting direction of the plurality of light-emitting devices, or an overlapping region between the first light-shielding structure and the plurality of light-emitting devices in a target light-emitting direction of the plurality of light-emitting devices is less than a set value.

2. The light-emitting substrate according to claim 1, wherein a material of the first light-shielding structure is a black matrix or a metal.

3. The light-emitting substrate according to claim 1, wherein the first light-shielding structure comprises a bottom portion, a side portion, and a top portion; the bottom portion of the first light-shielding structure faces towards the substrate; the side portion of the first light-shielding structure faces towards the plurality of light-emitting devices and surrounds the plurality of light-emitting devices; and the top portion of the first light-shielding structure is flush with or higher than a top end of the plurality of light-emitting devices.

4. The light-emitting substrate according to claim 1, wherein the first light-shielding structure is a single-layer or multi-layer structure.

5. The light-emitting substrate according to claim 1, wherein the light-emitting substrate further comprises a second light-shielding structure, and the second light-shielding structure is located at a side of a top end of the plurality of light-emitting devices and away from the top end of the plurality of light-emitting devices; a projection of the second light-shielding structure on a surface where the plurality of light-emitting devices are located is located at gaps between the plurality of light-emitting devices.

6. The light-emitting substrate according to claim 5, wherein the light-emitting substrate has a plurality of layers of the second light-shielding structure, and the plurality of layers of the second light-shielding structure are sequentially arranged at intervals in a target light-emitting direction of the plurality of light-emitting devices.

7. The light-emitting substrate according to claim 5, wherein a material of the second light-shielding structure is a black matrix or a metal.

8. The light-emitting substrate according to claim 1, wherein the light-emitting substrate comprises a plurality of light guide pillars, and a refractive index of a material of each of the plurality of light guide pillars is greater than a first set value; the plurality of light guide pillars corresponds to the plurality of light-emitting devices in a target light-emitting direction of the plurality of light-emitting devices.

9. The light-emitting substrate according to claim 8, wherein an inter-pillar structure is arranged between adjacent light guide pillars of the plurality of light guide pillars, a refractive index of the inter-pillar structure is less than a second set value, and the second set value is less than a first set value.

10. The light-emitting substrate according to claim 8, wherein the refractive index of the plurality of light guide pillars is 1.8-2.5.

11. The light-emitting substrate according to claim 9, wherein the refractive index of the inter-pillar structure is 1-1.5.

12. The light-emitting substrate according to claim 1, wherein the light-emitting substrate comprises one or more planarization layers covering the plurality of light-emitting devices, and a light transmittance of each of the one or more planarization layers covering the plurality of light-emitting devices is greater than 90%.

13. A method of manufacturing a light-emitting substrate, comprising:
forming a first light-shielding material layer, comprising forming, on a substrate having a plurality of light-emitting devices, the first light-shielding material layer covering the plurality of light-emitting devices and gaps between the plurality of light-emitting devices;
forming a first light-shielding structure, comprising removing a pattern of the first light-shielding material layer covering on the plurality of light-emitting devices in at least part of regions corresponding to the plurality of light-emitting devices to expose the at least part of the regions of the plurality of light-emitting devices.

14. The method of manufacturing a light-emitting substrate according to claim 13, further comprising:
performing a patterning process to form a second light-shielding material layer, wherein the second light-shielding material layer is formed and superimposed on the remaining first light-shielding material layer.

15. The method of manufacturing a light-emitting substrate according to claim 13, further comprising:
forming a second light-shielding structure, comprising forming one or more planarization layers, and forming a layer of light-shielding pattern in regions corresponding to gaps between the one or more planarization layers and the light-emitting devices, wherein the light-shielding pattern is the second light-shielding structure.

16. The method of manufacturing a light-emitting substrate according to claim 13, further comprising:
forming a plurality of light guide pillars in a target light-emitting direction of the plurality of light-emitting devices, wherein a refractive index of a material of the plurality of light guide pillars is greater than a first set value.

17. The light-emitting substrate according to claim 2, wherein the first light-shielding structure is a single-layer or multi-layer structure.

18. The light-emitting substrate according to claim 3, wherein the first light-shielding structure is a single-layer or multi-layer structure.

19. The light-emitting substrate according to claim 6, wherein a material of the second light-shielding structure is a black matrix or a metal.
